(19) United States
(12) Patent Application Publication
(10) Pub. No.: US 2025/0062214 A1
(43) Pub. Date: Feb. 20, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventor: Junghoo YUN, Suwon-si (KR)

(73) Assignee: SAMSUNG ELECTRONICS CO., LTD., Suwon-si (KR)

(21) Appl. No.: 18/753,334

(22) Filed: Jun. 25, 2024

(30) Foreign Application Priority Data
Aug. 14, 2023 (KR) 10-2023-0106420

(51) Int. Cl. H01L 23/498; H01L 23/00; H01L 23/31

(52) U.S. Cl. CPC H01L 23/49838; H01L 23/3128; H01L 23/49833; H01L 24/16; H01L 2224/16225; H01L 2924/1815

(57) ABSTRACT

A semiconductor package includes: a lower redistribution layer; a semiconductor chip on an upper surface of the lower redistribution layer, the semiconductor chip having an area that is less than an area of the lower redistribution layer; at least one plate group on the upper surface of the lower redistribution layer, each of the at least one plate group including a plurality of conductive plates facing each other and extending in a same direction; and a molding layer covering the upper surface of the lower redistribution layer and surrounding the semiconductor chip and the at least one plate group, wherein the plurality of conductive plates extend along a plane on the upper surface of the lower redistribution layer in a first horizontal direction and a second horizontal direction perpendicular to the first horizontal direction, and each of the plurality of conductive plates has a length in the first horizontal direction that is greater than a length in the second horizontal direction.

### CROSS-REFERENCE TO RELATED APPLICATION

This application is based on and claims priority under 35 U.S.C. § 119 to Korean Patent Application No. 10-2023-0106420, filed on Aug. 14, 2023, in the Korean Intellectual Property Office, the disclosure of which is incorporated by reference herein in its entirety.

### BACKGROUND

The disclosure relates to a semiconductor package and a method of manufacturing the same, and more particularly, to a semiconductor package including a redistribution layer and a method of manufacturing the same.

Recently, based on the rapid development of the electronics industry and consumer demands, electronic devices have become more compact, multi-functional, and higher capacity. Highly integrated semiconductor chips have been used to bring about these improvements. Semiconductor packages with good connection reliability, while including highly integrated semiconductor chips with a large number of input/output (I/O) connection terminals, have been developed.

### SUMMARY

Example embodiments provide a semiconductor package and a method of manufacturing the semiconductor package, capable of suppressing cracks in external connection terminals by uniformly arranging the external connection terminals on a redistribution layer.

Further, example embodiments provide a semiconductor package and a method of manufacturing the semiconductor package, capable of canceling noise by mounting a bypass capacitor.

The problem(s) to be solved by the disclosure is not limited to the problems mentioned above, and other problems may be clearly understood by those skilled in the art from the description below.

According to an aspect of the disclosure, a semiconductor package includes: a lower redistribution layer; a semiconductor chip on an upper surface of the lower redistribution layer, the semiconductor chip having an area that is less than an area of the lower redistribution layer; at least one plate group on the upper surface of the lower redistribution layer, each of the at least one plate group including a plurality of conductive plates facing each other and extending in a same direction; and a molding layer covering the upper surface of the lower redistribution layer and surrounding the semiconductor chip and the at least one plate group, wherein the plurality of conductive plates extend along a plane on the upper surface of the lower redistribution layer in a first horizontal direction and a second horizontal direction perpendicular to the first horizontal direction, and each of the plurality of conductive plates has a length in the first horizontal direction that is greater than a length in the second horizontal direction.

According to an aspect of the disclosure, a semiconductor package includes: a lower redistribution layer; a semiconductor chip on an upper surface of the lower redistribution layer, the semiconductor chip having an area that is less than an area of the lower redistribution layer; a conductive post on the upper surface of the lower redistribution layer and spaced apart from the semiconductor chip in a horizontal direction; a plate group on the upper surface of the lower redistribution layer, the plate group including a plurality of conductive plates facing each other and extending in a same direction; a molding layer covering the upper surface of the lower redistribution layer and surrounding the semiconductor chip, the conductive post, and the plate group; and an upper redistribution layer on the molding layer and the conductive post, wherein the plurality of conductive plates extend along a plane on the upper surface of the lower redistribution layer in a first horizontal direction and a second horizontal direction perpendicular to the first horizontal direction, and each of the plurality of conductive plates has a length in the first horizontal direction that is greater than a length in the second horizontal direction.

According to an aspect of the disclosure, a semiconductor package includes: a lower redistribution layer; a semiconductor chip on an upper surface of the lower redistribution layer, the semiconductor chip having an area that is less than an area of the lower redistribution layer; a conductive post on the upper surface of the lower redistribution layer and space apart from the semiconductor chip in a horizontal direction, the conductive post having a cylindrical shape; a first plate group including a plurality of first conductive plates on the upper surface of the lower redistribution layer and between the conductive post and the semiconductor chip, the plurality of first conductive plates facing each other and extending in a first same direction; a second plate group including a plurality of second conductive plates on the upper surface of the lower redistribution layer and between the conductive post and the semiconductor chip, facing each other, the plurality of second conductive plates extending in a second same direction; a molding layer covering the upper surface of the lower redistribution layer and surrounding the semiconductor chip, the conductive post, the first plate group, and the second plate group; and an upper redistribution layer on the molding layer and the conductive post, wherein each of the plurality of first conductive plates extends along a plane on the lower redistribution layer in a first horizontal direction and a second horizontal direction perpendicular to the first horizontal direction, the first horizontal direction of the plurality of first conductive plates is different from the first horizontal direction of the plurality of second conductive plates, a length of a diameter of the conductive post is less than a length of each of the plurality of first conductive plates in the first horizontal direction and greater than a length each of the plurality of first conductive plates in the second horizontal direction, and the length of the diameter of the conductive post is less than a length of each of the plurality of second conductive plates in the first horizontal direction and greater than a length of each of the plurality of second conductive plates in the second horizontal direction.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a plan view schematically illustrating a semiconductor package according to one or more embodiments;

FIG. 2 is a schematic cross-sectional view of a semiconductor package of FIG. 1, taken along line A-A′;

FIG. 3 is a schematic cross-sectional view of a semiconductor package according to one or more embodiments, taken along line A-A′ of FIG. 1;

FIG. 4 is a plan view schematically illustrating a semiconductor package according to one or more embodiments;

FIG. 5 is a plan view schematically illustrating a semiconductor package according to one or more embodiments;

FIG. 6 is a plan view schematically illustrating a semiconductor package according to one or more embodiments.

FIG. 7 is a schematic cross-sectional view of the semiconductor package of FIG. 6, taken along line B-B′;

FIG. 8 is a schematic cross-sectional view of a semiconductor package according to one or more embodiments, taken along line B-B′ of FIG. 6; and

FIG. 9 is a diagram illustrating a sequential process of a method of manufacturing a semiconductor package, according to at least one embodiment.

FIG. 10 is a diagram illustrating a sequential process of a method of manufacturing a semiconductor package, according to at least one embodiment.

FIG. 11 is a diagram illustrating a sequential process of a method of manufacturing a semiconductor package, according to at least one embodiment.

FIG. 12 is a diagram illustrating a sequential process of a method of manufacturing a semiconductor package, according to at least one embodiment.

FIG. 13 is a diagram illustrating a sequential process of a method of manufacturing a semiconductor package, according to at least one embodiment.

FIG. 14 is a diagram illustrating a sequential process of a method of manufacturing a semiconductor package, according to at least one embodiment.

FIG. 15 is a diagram illustrating a sequential process of a method of manufacturing a semiconductor package, according to at least one embodiment.

FIG. 16 is a diagram illustrating a sequential process of a method of manufacturing a semiconductor package, according to at least one embodiment.

### DETAILED DESCRIPTION

The embodiments may be modified in various forms and various embodiments may be provided, and thus, some embodiments are illustrated in the drawings and described in detail. However, it should be understood that the embodiments are not limited in scope.

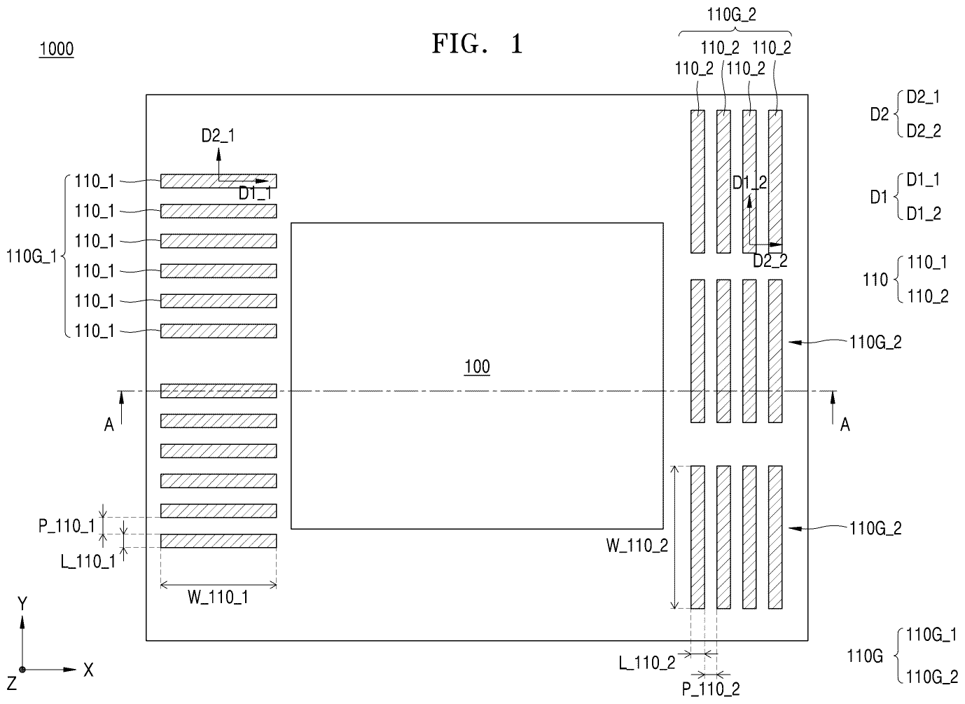

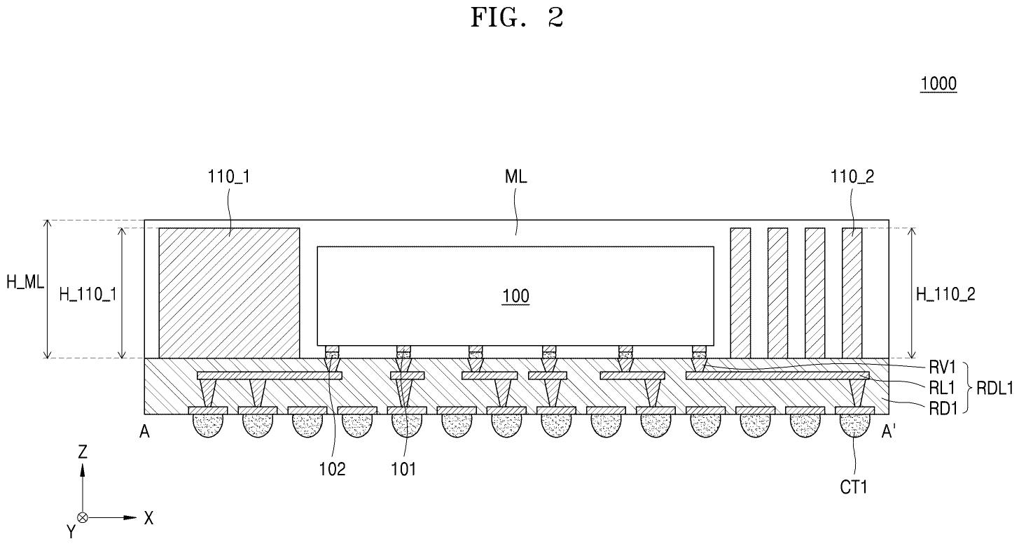

FIG. 1 is a plan view schematically illustrating a semiconductor package 1000 according to one or more embodiments. FIG. 2 is a schematic cross-sectional view of the semiconductor package 1000 of FIG. 1, taken along line A-A′.

Referring to FIGS. 1 and 2, the semiconductor package 1000 may include a lower redistribution layer RDL1, a first semiconductor chip 100, at least one plate group 110G, and a molding layer ML.

Hereinafter, unless otherwise defined, a direction parallel to an upper surface of the lower redistribution layer RDL1 is defined as a first direction (an X direction), a direction perpendicular to the upper surface of the lower redistribution layer RDL1 is defined as a vertical direction (a Z direction), and a direction perpendicular to the first direction (the X direction) and the vertical direction (the Z direction) is defined as a second direction (a Y direction).

The first semiconductor chip 100 of the semiconductor package 1000 may include an active surface and an inactive surface opposite to the active surface. In some embodiments, the first semiconductor chip 100 may be disposed on the upper surface of the lower redistribution layer RDL1 with the active surface of the first semiconductor chip 100 facing the lower redistribution layer RDL1.

The lower redistribution layer RDL1 of the semiconductor package 1000 may include a lower interconnection line RL1, a lower vertical via RV1 vertically extending from the lower interconnection line RL1, and a lower insulating layer RD1 surrounding the periphery of the lower interconnection line RL1 and the lower vertical via RV1.

In some embodiments, structurally, the lower vertical via RV1 in the lower redistribution layer RDL1 may have a width in the first direction (the X direction) and a width in the second direction (the Y direction) gradually increasing toward a lower surface of the first semiconductor chip 100. That is, the lower vertical via RV1 of the lower redistribution layer RDL1 may have a horizontal area increasing toward the first semiconductor chip 100.

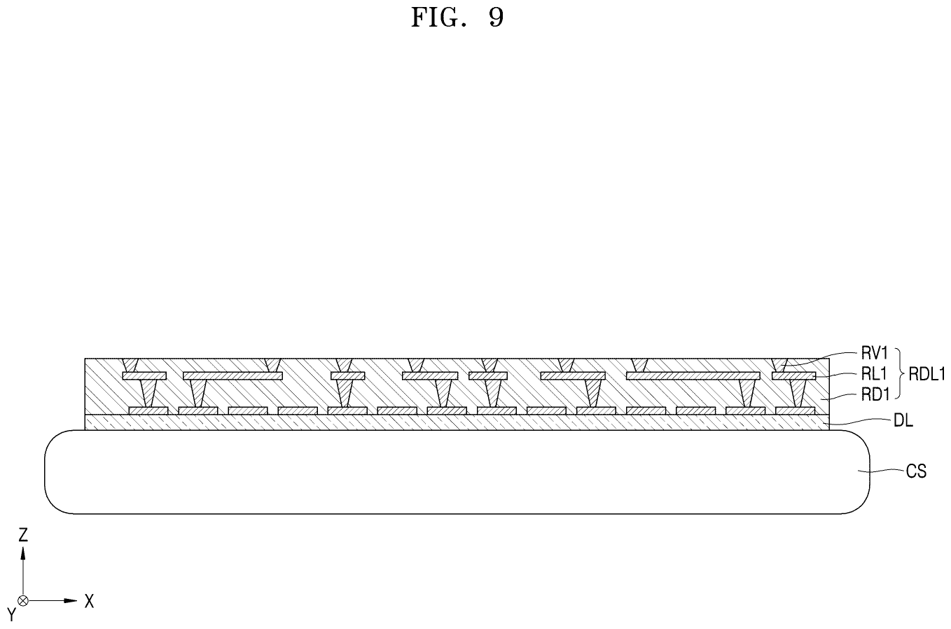

In some embodiments, the semiconductor package 1000 may have a chip-last structure in which the lower redistribution layer RDL1 is formed on a carrier substrate (CS in FIG. 9) and then the first semiconductor chip 100 is disposed on an upper surface of the lower redistribution layer RDL1.

An external connection terminal CT1 may be formed on the lower surface of the lower redistribution layer RDL1. The external connection terminal CT1 may include, for example, a combination of solder balls, conductive bumps, conductive paste, and a ball grid array (BGA).

Because the semiconductor package 1000 has only the external connection terminals CT1 on the lower surface of the lower redistribution layer RDL1, the external connection terminals CT1 may be uniformly disposed on the lower surface of the lower redistribution layer RDL1. Accordingly, all external connection terminals CT1 may receive substantially uniform stress from the outside, and the occurrence of cracks in some of the external connection terminals CT1 may be reduced.

The first semiconductor chip 100 of the semiconductor package 1000 may be located on the upper surface of the lower redistribution layer RDL1. The area of the upper surface of the first semiconductor chip 100 may be less than the area of the upper surface of the lower redistribution layer RDL1. For example, the lower redistribution layer RDL1 may extend outside the active surface of the first semiconductor chip 100 to expand a region in which a signal terminal is located.

The first semiconductor chip 100 may further include a chip pad 101 located on the active surface of the first semiconductor chip 100. The chip pad 101 may be electrically connected to individual devices on the active surface of the first semiconductor chip 100. The chip pad 101 may be electrically connected to the lower redistribution layer RDL1 through a connection terminal 102. The connection terminal 102 may be located between the lower redistribution layer RDL1 and the chip pad 101 and may be in direct contact with the lower redistribution layer RDL1 and the chip pad 101.

That is, the semiconductor package 1000 may have a fan-out wafer level package (FO-WLP) structure.

The first semiconductor chip 100 may include, for example, silicon (Si). Alternatively, the first semiconductor chip 100 may include a semiconductor element, such as germanium (Ge), or a compound semiconductor, such as silicon carbide (SiC), gallium arsenide (GaAs), indium arsenide (InAs), and indium phosphide (InP).

The first semiconductor chip 100 may include a conductive region, for example, a well doped with impurities or a structure doped with impurities. A semiconductor device layer including individual devices may be provided on the active surface of the first semiconductor chip 100. The individual devices may include, for example, a transistor. The individual devices may include microelectronic devices, for example, image sensors, such as a metal-oxide-semiconductor field effect transistor (MOSFET), a system large scale integration (LSI), a complementary metal-oxide semiconductor (CMOS) imaging sensor (CIS), etc . . . The individual devices may include microelectronic devices such as a micro-electronic-mechanical system (MEMS), active devices, passive devices, etc . . .

The first semiconductor chip 100 may be a memory chip or a logic chip. The memory chip may include a volatile memory semiconductor device, such as dynamic random access memory (DRAM) and static random access memory (SRAM). The memory chip may include a non-volatile memory semiconductor device, such as phase-change random access memory (PRAM), magnetoresistive random access memory (MRAM), ferroelectric random access memory (FeRAM), and resistive random access memory (RRAM). The logic chip may include a central processing unit (CPU) chip, a graphics processing unit (GPU) chip, an application processor (AP) chip, or an application specific integrated circuit (ASIC) chip.

In FIG. 1, one first semiconductor chip 100 is shown to be mounted on the upper surface of the lower redistribution layer RDL1, but the number of first semiconductor chips 100 is not limited thereto and two or more first semiconductors chips 100 may be mounted. When two or more first semiconductor chips 100 are mounted on the lower redistribution layer RDL1, the first semiconductor chips 100 may be different types of chips.

The plate group 110G of the semiconductor package 1000 may be located on the upper surface of the lower redistribution layer RDL1. For example, the plate group 110G may be located on a region of the upper surface of the lower redistribution layer RDL1 not overlapping the first semiconductor chip 100 in the vertical direction (the Z direction). The plate group 110G may include a plurality of conductive plates 110 facing each other and extending in the same direction.

The semiconductor package 1000 may include at least one plate group 110G. Although five plate groups 110G are shown in FIG. 1, the number of plate groups 110G is not limited thereto.

A direction in which the conductive plates 110 of the plate group 110G extend along a plane on the upper surface of the lower redistribution layer RDL1 may be a first horizontal direction D1, and a direction perpendicular to the first horizontal direction D1 may be a second horizontal direction D2. The first horizontal directions D1 of the respective conductive plates 110 included in one plate group 110G may be parallel to each other. For example, first horizontal directions D1_1 of the respective first conductive plates 110_1 of the first plate group 110G_1 may be the same.

The semiconductor package 1000 may include at least one type of plate group 110G. For example, the semiconductor package 1000 may include a first plate group 110G_1 and a second plate group 110G_2. In FIG. 1, the semiconductor package 1000 is shown to include two types of plate groups 110G, but the number of types of plate groups 110G is not limited thereto.

The first horizontal directions D1 of the conductive plates 110 included in the different types of plate groups 110G may not be parallel to each other. For example, the first horizontal direction D1_1 of the first conductive plates 110_1 of the first plate group 110G_1 may be different from the first horizontal direction D1_2 of the second conductive plates 110_2 of the second plate group 110G_2. In addition, the second horizontal direction D2_1 of the first conductive plates 110_1 of the first plate group 110G_1 may be different from the second horizontal direction D2_2 of the second conductive plates 110_2 of the second plate group 110G_2.

In FIG. 1, the first horizontal direction D1_1 of the first conductive plates 110_1 is shown to be perpendicular to the first horizontal direction D1_2 of the second conductive plates 110_2, but an intersection angle between the first horizontal directions D1 of the conductive plates 110 included in the different groups 110G is not limited thereto.

In some embodiments, the conductive plates 110 may include metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or alloys thereof but are not limited thereto.

Hereinafter, for convenience of description, the plate group 110G is described in detail using the first plate group 110G_1 as an example.

The first plate group 110G_1 may include at least two first conductive plates 110_1. The first plate group 110G_1 may function as a bypass capacitor through at least two first conductive plates 110_1 facing each other. For example, the first plate group 110G_1 may remove noise from signals input/output to/from the first semiconductor chip 100.

A length W_110_1 of the first conductive plates 110_1 of the first plate group 110G_1 in the first horizontal direction D1_1 may be greater than a length L_110_1 of the first conductive plates 110_1 of the first plate group 110G_1 in the second horizontal direction D2_1. The first conductive plates 110_1 may have a thin and long shape. In some embodiments, the length W_110_1 of the first conductive plates 110_1 in the first horizontal direction D1_1 may be ten to 100 times the length L_110_1 of the first conductive plates 110_1 in the second horizontal direction D2_1.

In some embodiments, the length L_110_1 of each of the first conductive plates 110_1 in the second horizontal direction D2_1 may be about 20 μm to about 100 μm. For example, the first conductive plates 110_1 may be thin plates standing on the upper surface of the lower redistribution layer RDL1. In some embodiments, the cross-section of the first conductive plates 110_1 may have a polygonal shape. In this specification, a cross-section refers to a surface cut in a direction perpendicular to the vertical direction (the Z direction).

In some embodiments, the first conductive plates 110_1 may be separated from each other in the second horizontal direction D2_1. In detail, the first conductive plates 110_1 may be separated from each other at equal intervals in the second horizontal direction D2_1. The molding layer ML may fill a space between the first conductive plates 110_1 that are separated from each other. Accordingly, the first plate group 110G_1 may function as a capacitor. In some embodiments, a distance P_110_1 between two adjacent first conductive plates 110_1, among the first conductive plates 110_1, separated from each other in the second horizontal direction D2_1 may be about 3 μm to about 40 μm. In FIG. 1, although the first conductive plates 110_1 are all shown to have the same length L_110_1 in the second horizontal direction D2_1, the disclosure is not limited thereto, and the first conductive plates 110_1 may have the different lengths L_110_1 in t second horizontal directions D2_1.

In some embodiments, lengths H_110_1 of the respective first conductive plates 110_1 in the vertical direction (the Z direction) may be equal to each other. The first conductive plates 110_1 may be formed simultaneously through a conductive process, so that the first conductive plates 110_1 may all have the length H_110_1 in the same vertical direction (the Z direction).

In some embodiments, the length H_110_1 of the first conductive plates 110_1 in the vertical direction (the Z direction) may be less than the length H_ML of the molding layer ML in the vertical direction (the Z direction). That is, the upper surface of the first conductive plates 110_1 may be covered with the molding layer ML. In order to suppress damage to the first conductive plates 110_1 during a polishing process of removing an upper portion of the molding layer ML, the upper portion of the molding layer ML may be removed so that the first conductive plates 110_1 are buried within the molding layer ML.

The second plate group 110G_2 may be substantially the same as the first plate group 110G_1, and each of the first horizontal direction D1_2 and the second horizontal direction D2_2 of the second conductive plates 110_2 may be respectively different from the first horizontal direction D1_1 and the second horizontal direction D2_1 of the first conductive plates 110_1. For example, the first horizontal direction D1_1 of the first conductive plates 110_1 may be parallel to the first direction (the X direction), and the first horizontal direction D1_2 of the second conductive plates 110_2 may be parallel to the second direction (the Y direction).

A length W_110_2 of each of the second conductive plates 110_2 in the first horizontal direction D1_2 may be greater than a length L_110_2 of each of the second conductive plates 110_2 in the second horizontal direction D2_2.

For example, the length W_110_2 of each of the second conductive plates 110_2 in the first horizontal direction D1_2 may be ten to 100 times the length L_110_2 of each of the second conductive plates 110_2 in the second horizontal direction D2_2. In some embodiments, the length L_110_2 of each of the second conductive plates 110_2 in the second horizontal direction D2_2 may be about 20 μm to about 100 μm. In some embodiments, a distance P_110_2 between the second conductive plates 110_2 in the second horizontal direction D2_2 may be about 3 μm to about 40 μm.

In some embodiments, a length H_110_2 of the second conductive plates 110_2 in the vertical direction (the Z direction) may be less than the length H_ML of the molding layer ML in the vertical direction (the Z direction).

In some embodiments, the length H_110_1 of the first conductive plates 110_1 in the vertical direction (the Z direction) may be equal to the length H_110_2 of the second conductive plates 110_2 in the vertical direction (the Z direction). In detail, the first conductive plates 110_1 and the second conductive plates 110_2 may be formed simultaneously through a plating process, and the lengths H_110_1 and H_110_2 of the first conductive plates 110_1 and the second conductive plates 110_2 in the vertical direction (the Z direction) may be equal to each other.

The molding layer ML may cover the upper surface of the lower redistribution layer RDL1 and may surround the first semiconductor chip 100 and the plate group 110G. In some embodiments, the molding layer ML may include epoxy resin or polyimide resin. The molding layer ML may include, for example, epoxy molding compound (EMC).

A horizontal width of the molding layer ML may be substantially equal to a horizontal width of the lower redistribution layer RDL1. For example, a side surface of the molding layer ML may be substantially coplanar with a side surface of the lower redistribution layer RDL1.

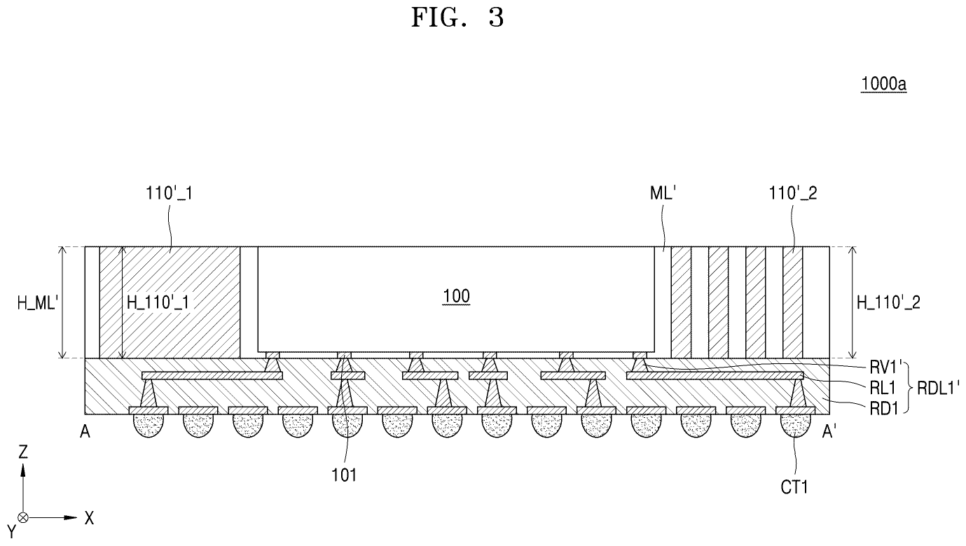

FIG. 3 is a schematic cross-sectional view of a semiconductor package 1000a according to one or more embodiments, taken along line A-A′ of FIG. 1.

Referring to FIG. 3 together with FIG. 1, the semiconductor package 1000a may include a lower redistribution layer RDL1′, the first semiconductor chip 100, at least one plate group 110G, and a molding layer ML′.

Most of the components constituting the semiconductor package 1000a described below and the materials forming the components are substantially the same as or similar to those described above with reference to FIG. 1. Therefore, for convenience of description, the description focuses on the differences between the semiconductor package 1000a of FIG. 3 and the semiconductor package 1000 of FIG. 1 described above.

The semiconductor package 1000a may have a chip-first structure. In detail, the semiconductor package 1000a may have a structure in which the first semiconductor chip 100 is mounted on a carrier substrate (CS in FIG. 9) and a lower redistribution layer RLD1′ is then formed on the first semiconductor chip 100.

The lower redistribution layer RDL1′ of the semiconductor package 1000a may include the lower interconnection line RL1, a lower vertical via RV1′ vertically extending from the lower interconnection line RL1, and the lower insulating layer RD1 surrounding the periphery of the lower interconnection line RL1 and the lower vertical via RV1′.

In some embodiments, structurally, the lower vertical via RV1′ in the lower redistribution layer RDL1′ may have a width in the first direction (the X direction) and/or a width in the second direction (the Y direction) gradually decreasing toward the lower surface of the first semiconductor chip 100. That is, the lower vertical via RV1′ of the lower redistribution layer RDL1′ may have a horizontal area decreasing toward the first semiconductor chip 100.

The first semiconductor chip 100 of the semiconductor package 1000a may be located on the lower redistribution layer RDL1′. The chip pad 101 located on the active surface of the first semiconductor chip 100 may directly contact the lower redistribution layer RDL1′.

For example, a length H_110′_1 of the first conductive plates 110′_1 of the first plate group 110G_1 in the vertical direction (the Z direction) may be equal to a length H_ML′ of the molding layer ML′ in the vertical direction (the Z direction). An upper surface of the first conductive plates 110′_1 may be coplanar with an upper surface of the molding layer ML′. In some embodiments, the upper surface of the first semiconductor chip 100, the upper surface of the first conductive plates 110′_1, and the upper surface of the molding layer ML′ may be coplanar with each other. For example, the first conductive plates 110′_1 may completely pass through the molding layer ML′.

In some embodiments, a length H_110′_1 of the first conductive plates 110′_1 of the first plate group 110G_1 in the vertical direction (the Z direction) may be equal to a length H_110′_2 of the second conductive plates 110′_2 of the second plate group 110G_2 in the vertical direction (the Z direction).

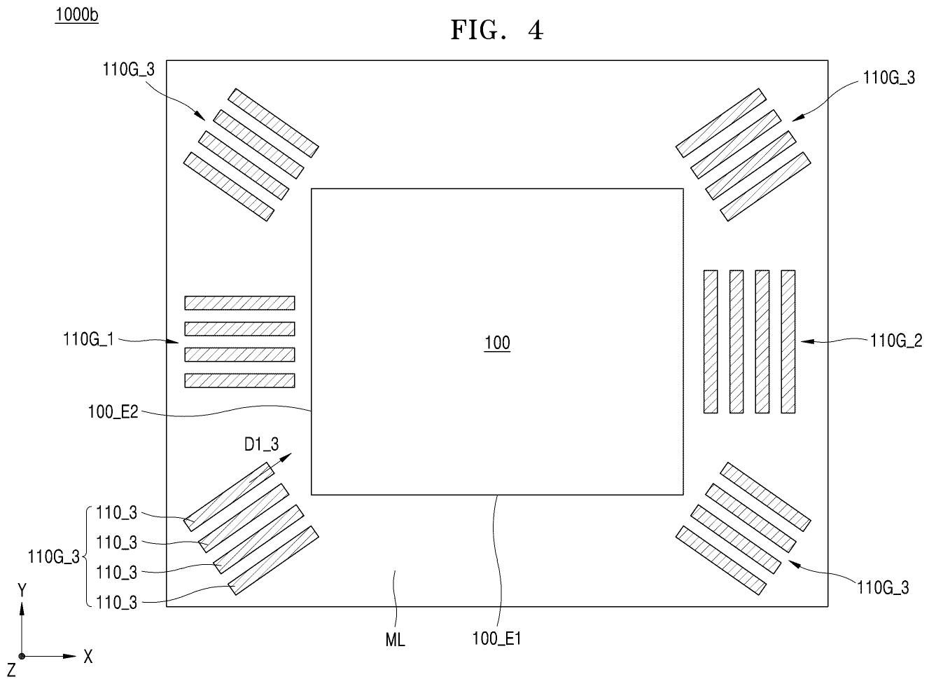

FIG. 4 is a plan view schematically illustrating a semiconductor package 1000b according to one or more embodiments.

Referring to FIG. 4 together with FIGS. 1 and 2, the semiconductor package 1000b may include the lower redistribution layer RDL1, the first semiconductor chip 100, at least one plate group 110G, and the molding layer ML′.

Most of the components constituting the semiconductor package 1000b described below and the materials forming the components are substantially the same as or similar to those described above with reference to FIG. 1. Therefore, for convenience of description, the description focuses on the differences between the semiconductor package 1000b of FIG. 4 and the semiconductor package 1000 of FIG. 1 described above.

At least one plate group 110G of the semiconductor package 1000b may include a third plate group 110G_3. For example, at least one plate group 110G may include first to third plate groups 110G_1, 110G_2, and 110G_3.

The first horizontal direction D1_1 of the first conductive plates 110_1 of the first plate group 110G_1 may be parallel to an extension direction of a first edge 100_E1 of the first semiconductor chip 100, and the first horizontal direction D1_2 of the second conductive plates 110_2 of the second plate group 110G_2 may be parallel to an extension direction of a second edge 100_E2 of the first semiconductor chip 100. In some embodiments, the first plate group 110G_1 and the second plate group 110G_2 may be located near four edges of the first semiconductor chip 100.

A first horizontal direction D1_3 of the third conductive plates 110_3 of the third plate group 110G_3 may not be parallel to the extension directions of the four edges of the first semiconductor chip 100. For example, the first horizontal direction D1_3 of the third conductive plates 110_3 may not be parallel to the extension direction of the first edge 100_E1 and the extension direction of the second edge 100_E2 of the first semiconductor chip 100. In some embodiments, the first horizontal direction D1_3 of the third conductive plates 110_3 may be inclined toward the extension direction of the second edge 100_E2 with respect to the extension direction of the first edge 100_E1 of the first semiconductor chip 100. For example, the first horizontal direction D1_3 of the third conductive plates 110_3 may be 45 degrees in the extension direction of the second edge 100_E2 with respect to the extension direction of the first edge 100_E1 of the first semiconductor chip 100.

In some embodiments, the third plate group 110G_3 may be located near the vertex of the upper surface of the first semiconductor chip 100. For example, the third conductive plates 110_3 of the third plate group 110G_3 may along a plane extend from the vertex of the upper surface of the molding layer ML toward the vertex of the upper surface of the first semiconductor chip 100. The third plate group 110G_3 may be located between the vertex of the upper surface of the molding layer ML and the vertex of the upper surface of the first semiconductor chip 100.

In the process of forming the molding layer ML, the first horizontal direction D1_3 of the third conductive plates 110_3 may be parallel to a flow direction of a molding liquid of the molding layer ML. Accordingly, in the process of forming the molding layer ML, a phenomenon in which the third conductive plates 110_3 interferes with flow of the molding liquid of the molding layer ML may be suppressed.

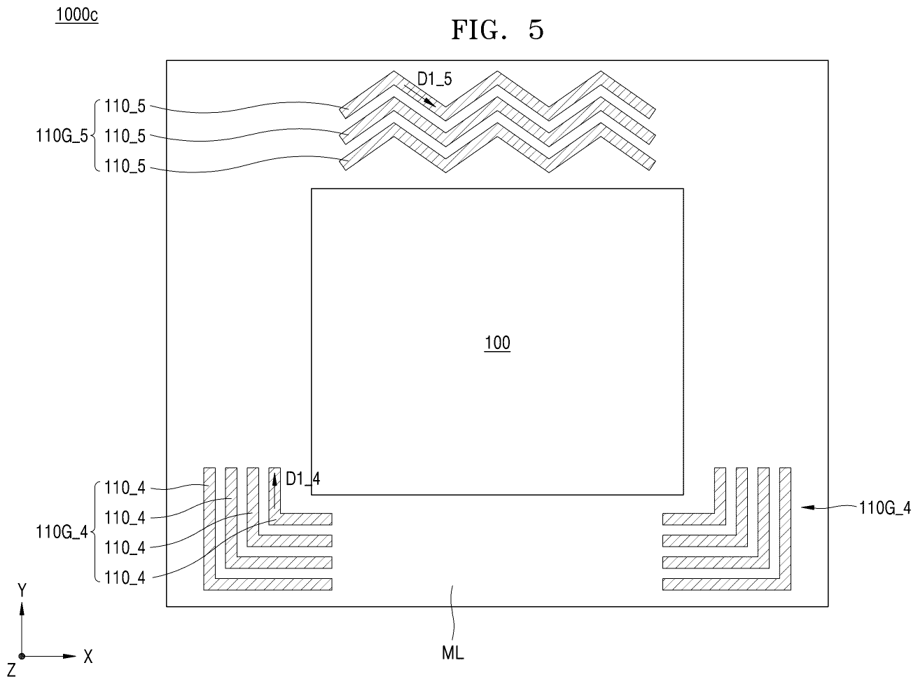

FIG. 5 is a plan view schematically illustrating a semiconductor package 1000c according to one or more embodiments.

Referring to FIG. 5 together with FIGS. 1 and 2, the semiconductor package 1000c may include the lower redistribution layer RDL1, the first semiconductor chip 100, at least one plate group 110G, and the molding layer ML.

Most of the components constituting the semiconductor package 1000c described below and the materials forming the components are substantially the same as or similar to those described above with reference to FIG. 1. Therefore, for convenience of description, the description focuses on the differences between the semiconductor package 1000c of FIG. 5 and the semiconductor package 1000 of FIG. 1 described above.

At least one plate group 110G of the semiconductor package 1000c may include a fourth plate group 110G_4 and a fifth plate group 110G_5. In FIG. 5, at least one plate group 110G is shown to include only the fourth plate group 110G_4 and the fifth plate group 110G_5, but the disclosure is not limited thereto, and at least one plate group 110G may further include the first to third plate groups 110G_1, 110G_2, and 110G_3 described above.

The cross-sections of the fourth conductive plates 110_4 of the fourth plate group 110G_4 and the cross-sections of the fifth conductive plates 110_5 of the fifth plate group 110G_5 may have a bent shape. For example, each of the fourth conductive plates 110_4 and the fifth conductive plates 110_5 may include a plurality of regions in which the first horizontal directions D1_4 and D1_5 are different from each other.

In some embodiments, the fourth conductive plates 110_4 may include a region in which the first horizontal direction D1_4 is parallel to the extension direction of the first edge (100_E1 in FIG. 4) of the first semiconductor chip 100 and a region in which the first horizontal direction D1_4 is parallel to an extension direction of the second edge (100_E2 in FIG. 4) of the first semiconductor chip 100. That is, the fourth conductive plates 110_4 may include two orthogonal regions. For example, the cross-section of each of the fourth conductive plates 110_4 may be ‘L’ shaped.

In some embodiments, the fourth plate group 110G_4 may be located near the vertex of the upper surface of the first semiconductor chip 100. For example, a distance between the fourth plate group 110G_4 and the vertex of the upper surface of the first semiconductor chip 100 is relatively small, so a greater number of fourth conductive plates 110_4 may be arranged in the same area.

In some embodiments, the fifth conductive plates 110_5 may include a plurality of regions in which first horizontal directions D1_5 are different from each other. For example, the fifth conductive plates 110_5 may include two regions, in which the first horizontal directions are different from each other, extending alternately. That is, the cross-section of the fifth conductive plates 110_5 may have a zigzag bent shape. Here, the cross-sectional shapes of the fifth conductive plates 110_5 may be the same as each other. That is, the fifth conductive plates 110_5 may extend in the same direction.

For example, the facing area between the fifth conductive plates 110_5 may be relatively large, so the performance of the fifth plate group 110G_5 may be improved.

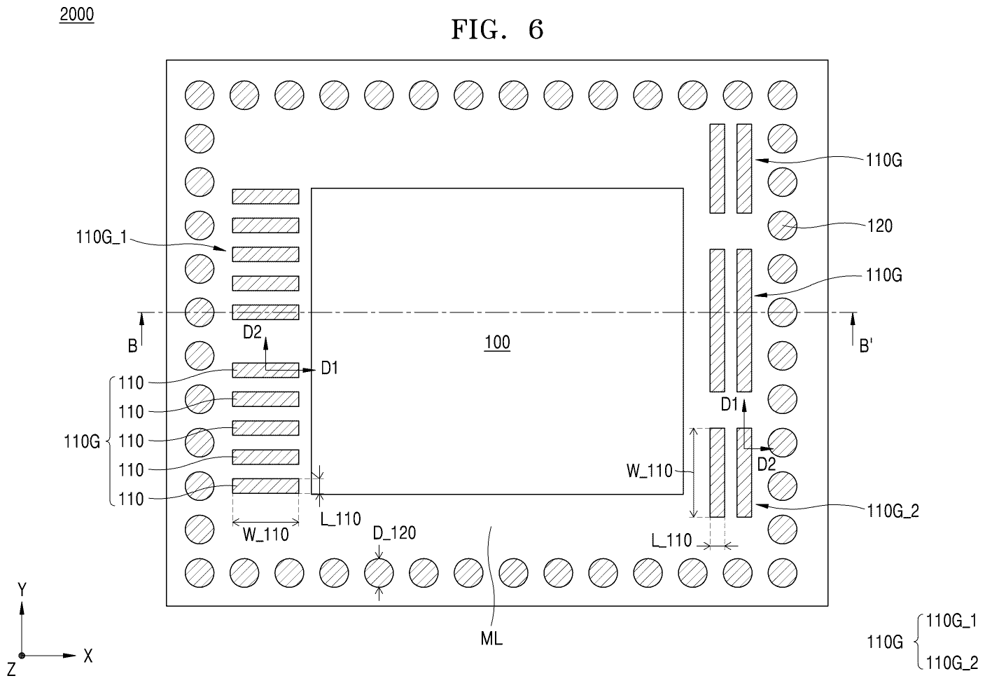

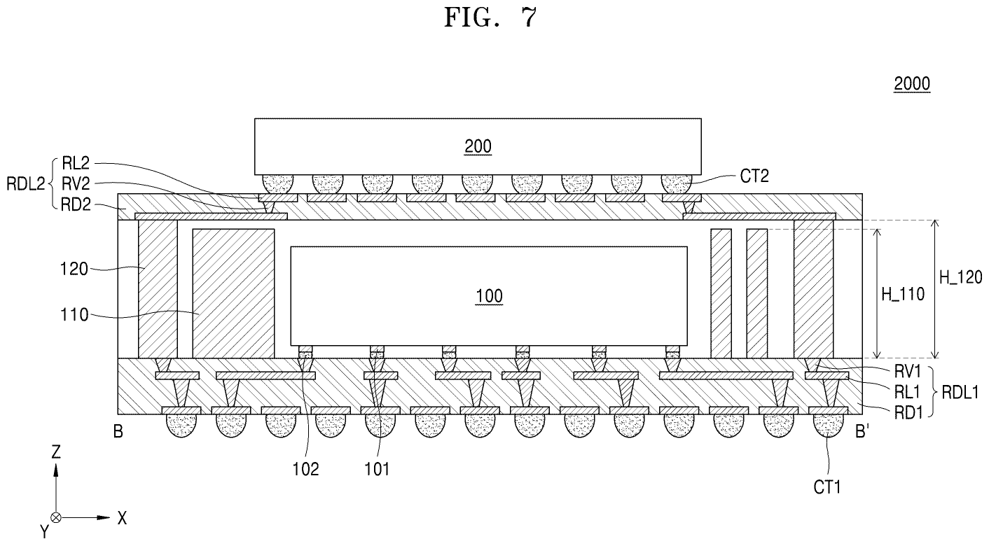

FIG. 6 is a plan view schematically illustrating a semiconductor package 2000 according to one or more embodiments. FIG. 7 is a schematic cross-sectional view of the semiconductor package 2000 of FIG. 6, taken along line B-B′.

A package-on-package (PoP)-type semiconductor package in which an upper semiconductor package is mounted on a lower semiconductor package is described with reference to FIGS. 6 and 7.

Referring to FIGS. 6 and 7, the semiconductor package 2000 may include the lower redistribution layer RDL1, the first semiconductor chip 100, a conductive post 120, the plate group 110G, the molding layer ML, and an upper redistribution layer RDL2. In some embodiments, the semiconductor package 2000 may further include a second semiconductor chip 200.

Most of the components constituting the semiconductor package 2000 described below and the materials forming the components are substantially the same as or similar to those described above with reference to FIG. 1. Therefore, for convenience of description, the description focuses on the differences between the semiconductor package 2000 of FIG. 6 and the semiconductor package 1000 of FIG. 1 described above.

In FIG. 7, the plate group 110G of the semiconductor package 2000 may include at least one of the first to fifth plate groups 110G_1, 110G_2, 110G_3, 110G_4, or 110G_5 described above. For example, the semiconductor package 2000 may include different types of plate groups 110G. For example, the first horizontal directions D1, which is the direction in which the conductive plates 110 of each of the plate groups 110G disposed on the lower redistribution layer RDL1 extend, may be different from each other.

The plate group 110G may be located between the conductive post 120 and the first semiconductor chip 100. For example, the conductive post 120 may be located near the edge of the lower redistribution layer RDL1, the first semiconductor chip 100 may be located at the center of the upper surface of the lower redistribution layer RDL1, and the plate group 110G may be located between the first semiconductor chip 100 and the conductive post 120.

For example, a length W_110 of each of the conductive plates 110 of the plate group 110G in the first horizontal direction D1 may be greater than the length L_110 of each of the conductive plates 110 of the plate group 110G in the second horizontal direction D2. That is, each of the conductive plates 110 may have a shape that extends thinly and long along a plane on the lower redistribution layer RDL1. For example, the length W_110 of each of the conductive plates 110 in the first horizontal direction D1 may be ten to 100 times the length L_110 in the second horizontal direction D2.

In FIG. 7, the semiconductor package 2000 is shown as a chip-last structure as in FIG. 2, but the disclosure is not limited thereto and the semiconductor package 2000 may have the chip-first structure as in FIG. 3. That is, the horizontal area of the lower vertical via RV1 of the lower redistribution layer RDL1 may vary toward the first semiconductor chip 100.

The conductive post 120 of the semiconductor package 2000 may be located on the upper surface of the lower redistribution layer RDL1. The conductive post 120 may be formed near the edge of the upper surface of the lower redistribution layer RDL1. In FIG. 6, the conductive posts 120 are shown to be arranged in a row, but the conductive posts 120 may be arranged in multiple rows.

The conductive post 120 may be electrically connected to the lower redistribution layer RDL1. The conductive post 120 may electrically connect the lower redistribution layer RDL1 to the upper redistribution layer RDL2. The conductive plates 110 of the plate group 110G may be electrically connected to the lower redistribution layer RDL1 and may not be electrically connected to the upper redistribution layer RDL2.

In some embodiments, the length H_120 of the conductive post 120 in the vertical direction (the Z direction) may be different from the length H_110 of the conductive plates 110 of the plate group 110G in the vertical direction (the Z direction). However, the disclosure is not limited thereto, and as shown in FIG. 3, the length H_120 of the conductive post 120 in the vertical direction (the Z direction) may be equal to the length H_110 of the conductive plates 110 in the vertical direction (the Z direction).

In some embodiments, the upper portions of the conductive plates 110 of the plate group 110G may be covered with the molding layer ML, and the conductive posts 120 may completely penetrate the molding layer ML. That is, the conductive plates 110 may be separated from the upper redistribution layer RDL2 with the molding layer ML therebetween, and the conductive post 120 may be in direct contact with the upper redistribution layer RDL2. For example, the length H_120 of the conductive post 120 in the vertical direction (the Z direction) may be greater than the length H_110 of the conductive plates 110 of the plate group 110G in the vertical direction (the Z direction).

In some embodiments, the conductive post 120 may have a pillar shape with a circular cross-section. That is, the conductive post 120 may have a cylindrical shape. A diameter D_120 of the conductive post 120 may be about 60 μm to about 300 μm.

In some embodiments, the diameter D_120 of the conductive post 120 may be less than the length W_110 of the conductive plates 110 in the first horizontal direction D1. The diameter D_120 of the conductive post 120 may be greater than the length L_110 of the conductive plates 110 in the second horizontal direction D2. For example, the cross-section of each of the conductive plates 110 may be thinner in the second horizontal direction D2 and may have a rectangular shape that is longer in the first horizontal direction D1 than the cross-section of the conductive post 120.

In some embodiments, the conductive post 120 may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or alloys thereof but is not limited thereto.

In some embodiments, the conductive post 120 may include the same constituent material as that of the conductive posts 120 of the plate group 110G. For example, the conductive post 120 and the conductive plates 110 of the plate group 110G may be formed simultaneously through a conductive process. Accordingly, the conductive post 120 and the conductive plates 110 may include the same constituent material.

The molding layer ML of the semiconductor package 2000 may be located on the lower redistribution layer RDL1. The molding layer ML may surround the conductive post 120, the plate group 110G, and the first semiconductor chip 100. The molding layer ML may fill a space between the conductive plates 110 of the plate group 110G. For example, the molding layer ML may include a dielectric material. Accordingly, the molding layer ML located in the space between the conductive plates 110 may function as a dielectric of a capacitor.

The upper redistribution layer RDL2 of the semiconductor package 2000 may be located on the molding layer ML and the conductive post 120. The upper redistribution layer RDL2 may include an upper interconnection line RL2, an upper vertical via RV2 vertically extending from the upper interconnection line RL2, and an upper insulating layer RD2 surrounding the periphery of the upper interconnection line RL2 and the upper vertical via RV2.

Structurally, the upper vertical via RV2 located inside the upper redistribution layer RDL2 may have a width gradually decreasing in the first direction (the X direction) and/or the second direction (the Y direction) toward the upper surface of the first semiconductor chip 100. For example, a horizontal area of the upper vertical via RV of the upper redistribution layer RDL2 may decrease toward the first semiconductor chip 100.

The second semiconductor chip 200 of the semiconductor package 2000 may be disposed on the upper redistribution layer RDL2. The second semiconductor chip 200 may have active and inactive surfaces opposite to each other each other.

The second semiconductor chip 200 may include, for example, silicon (Si). Alternatively, the second semiconductor chip 200 may include a semiconductor element, such as germanium (Ge), or a compound semiconductor, such as silicon carbide (SiC), gallium arsenide (GaAs), indium arsenide (InAs), and indium phosphide (InP).

The second semiconductor chip 200 may include a conductive region, for example, a well doped with impurities or a structure doped with impurities. A semiconductor device layer including individual devices may be provided on the active surface of the second semiconductor chip 200. The individual devices may include, for example, a transistor. The individual devices may include microelectronic devices, for example, image sensors, such as a MOSFET, a system LSI, a CIS, etc., an MEMS, active devices, passive devices, etc.

The second semiconductor chip 200 may be a memory chip or a logic chip. The memory chip may include a volatile memory semiconductor device, such as DRAM and SRAM, or a non-volatile memory semiconductor device, such as PRAM, MRAM, FeRAM, and RRAM. The logic chip may include a CPU chip, a GPU chip, an AP chip, or an ASIC chip.

In some embodiments, the first semiconductor chip 100 may be a memory chip, and the second semiconductor chip 200 may be a logic chip including a logic device. For example, the first semiconductor chip 100 may be a memory chip and may include a volatile memory chip and/or a non-volatile memory chip. The second semiconductor chip 200 may be a logic chip and may include a CPU chip, a GPU chip, or an AP chip. That is, the second semiconductor chip 200 may function different than the first semiconductor chip 100.

In some embodiments, the second semiconductor chip 200 may be disposed on the upper redistribution layer RDL2 with the active surface of the second semiconductor chip 200 facing the upper redistribution layer RDL2. Here, the second semiconductor chip 201 may be electrically connected to the upper redistribution layer RDL2 through an internal connection terminal CT2 formed between the second semiconductor chip 201 and the upper redistribution layer RDL2. That is, the second semiconductor chip 200 may be electrically connected to the lower redistribution layer RDL through the internal connection terminal CT2, the upper redistribution layer RDL2, and the conductive post 120.

In some embodiments, the second semiconductor chip 200 may be disposed on the upper redistribution layer RDL2 such that the inactive surface of the second semiconductor chip 200 faces the upper redistribution layer RDL2. The second semiconductor chip 200 may be electrically connected to the upper redistribution layer RDL2 through a conductive wire.

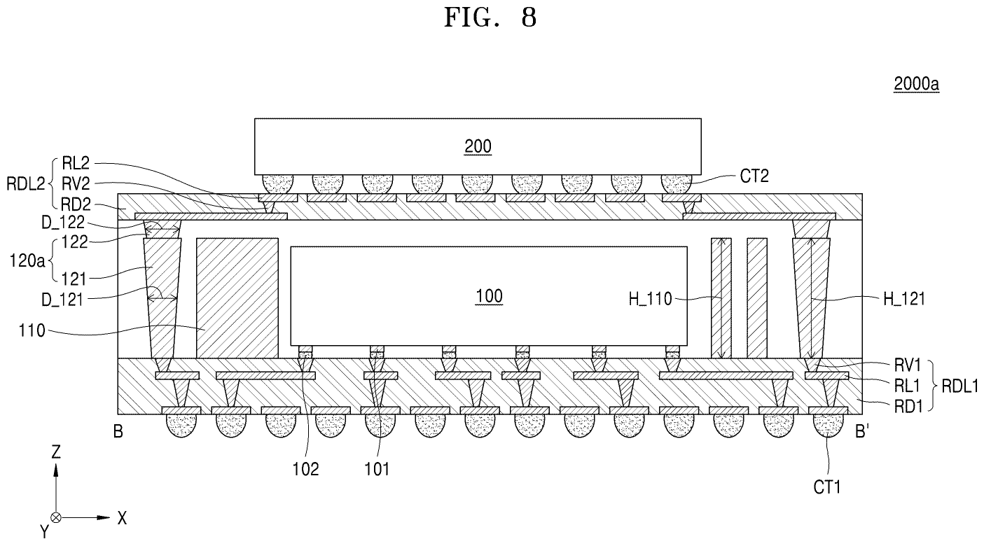

FIG. 8 is a schematic cross-sectional view of a semiconductor package 2000a according to one or more embodiments, taken along line B-B′ in FIG. 6.

Referring to FIG. 8, the semiconductor package 2000a may include the lower redistribution layer RDL1, the first semiconductor chip 100, a conductive post 120a, the plate group 110G, the molding layer ML, and the upper redistribution layer RDL2. In some embodiments, the semiconductor package 2000a may further include the second semiconductor chip 200.

Most of the components constituting the semiconductor package 2000a described below and the materials forming the components are substantially the same as or similar to those described above with reference to FIG. 6. Therefore, for convenience of description, the description focuses on the differences between the semiconductor package 2000a of FIG. 8 and the semiconductor package 2000 of FIG. 6 described above.

A conductive post 120a of the semiconductor package 2000a may include an upper post 122 and a lower post 121. A lower surface of the lower post 121 may contact the lower redistribution layer RDL1, and an upper surface of the lower post 121 may contact the upper post 122. The upper post 122 may contact the lower post 121 from a lower surface of the upper post 122, and may contact the upper redistribution layer RDL2 from an upper surface of the upper post 122.

A horizontal width D_122 of the upper post 122 may decrease toward the lower redistribution layer RDL1. A horizontal width D_121 of the lower post 121 may decrease toward the lower redistribution layer RDL1. In FIG. 8, the conductive post 120a is shown to have a two-stage structure including the upper post 122 and the lower post 121, but the disclosure is not limited thereto, and the conductive post 120a may have a three-stage structure or more.

In some embodiments, the horizontal width D_121 of the upper surface of the lower post 121 may be different from the horizontal width D_122 of the lower surface of the upper post 122. For example, the horizontal width D_121 of the upper surface of the lower post 121 may be greater than the horizontal width D_122 of the lower surface of the upper post 122.

In some embodiments, a length H_121 of the lower post 121 in the vertical direction (the Z direction) may be equal to a length H_110 of the conductive plates 110 in the vertical direction (the Z direction). For example, the lower post 121 and the conductive plates 110 maybe formed together through a plating process, so that the length H_121 of the lower post 121 in the vertical direction (the Z direction) may be equal to the length H_110 of the conductive plates 110 in the vertical direction (the Z direction).

For example, the length of the upper post 122 in the vertical direction (the Z direction) may be equal to a distance between the upper surface of the conductive plates 110 and the lower surface of the upper redistribution layer RLD2. That is, the distance between the upper surface of the molding layer ML and the upper surfaces of the conductive plates 110 may be equal to the length of the upper post 122 in the vertical direction (the Z direction).

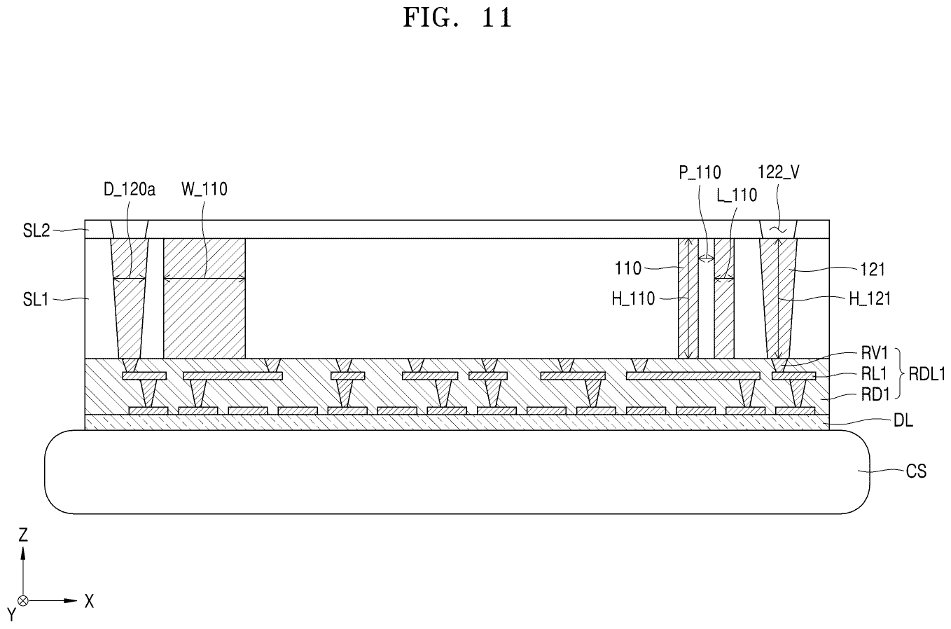

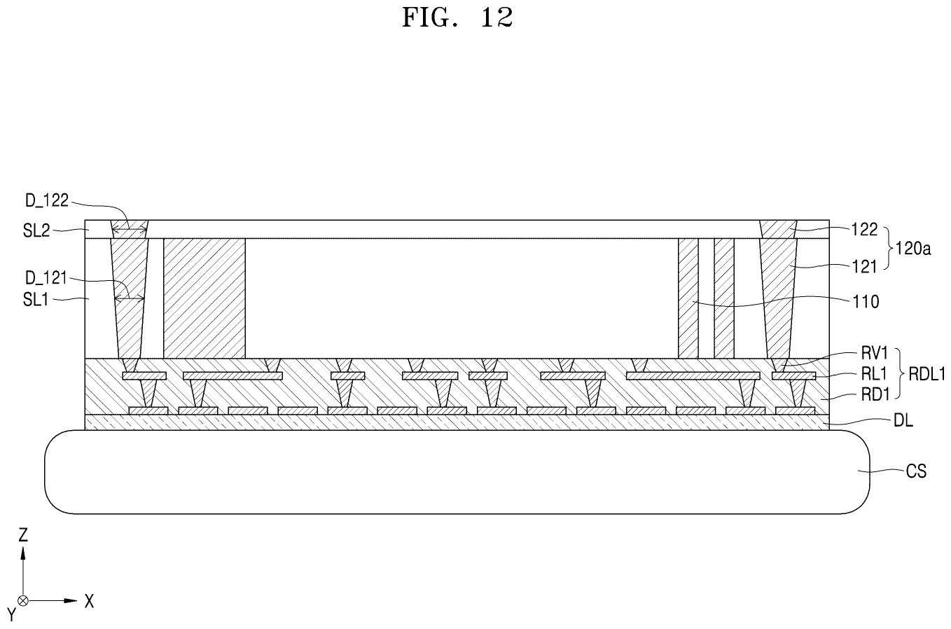

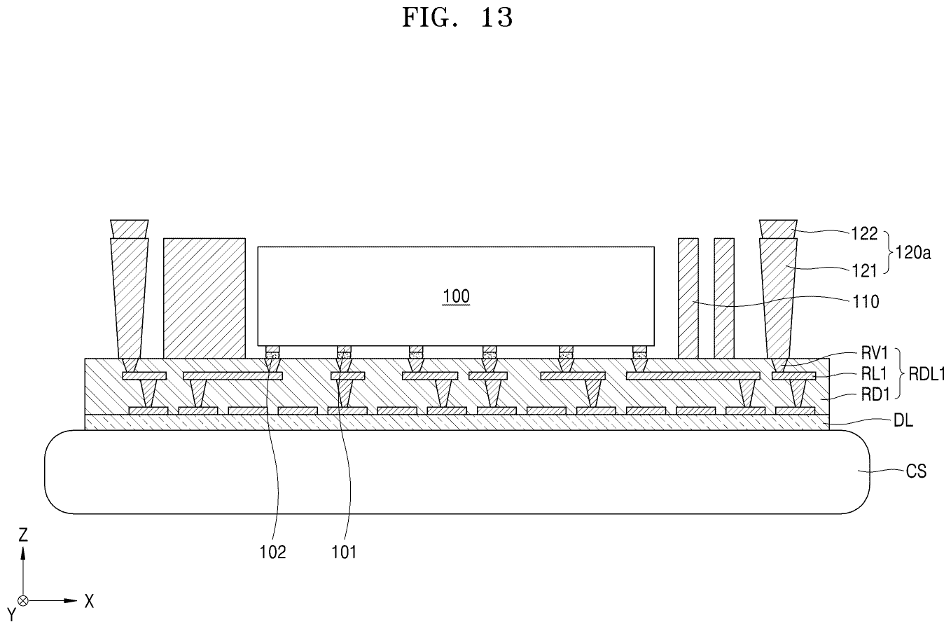

FIGS. 9 to 16 are diagrams illustrating a sequential process of a method of manufacturing a semiconductor package, according to one or more embodiments.

Hereinafter, the method of manufacturing a semiconductor package is described in detail with reference to FIGS. 9 to 16.

Referring to FIG. 9, an adhesive insulating layer DL may be attached to the carrier substrate CS, and the lower redistribution layer RDL1 may be formed on the adhesive insulating layer DL.

The carrier substrate CS may include, for example, glass, silicon, or aluminum oxide. The adhesive insulating layer DL may include any material capable of fixing the lower redistribution layer RDL1. The adhesive insulating layer DL may be, for example, an adhesive tape having adhesive strength that is weakened by heat treatment or laser irradiation.

In some embodiments, the lower redistribution layer RDL1 may be formed on the adhesive insulating layer DL through a plating process or a deposition process.

The lower redistribution layer RDL1 may include the lower interconnection line RL1, the lower vertical via RV1 vertically connecting the lower interconnection line RL1, and the lower insulating layer RD1 surrounding the periphery of the lower interconnection line RL1 and the lower vertical via RV1.

As shown in FIGS. 9 to 16, in the method of manufacturing a semiconductor package having a chip-last structure, the horizontal width of the lower vertical via RV1 may increase away from the carrier substrate CS. However, the disclosure is not limited thereto, and in a method of manufacturing a semiconductor package having a chip-first structure, the lower vertical via RV1 may decrease away from the carrier substrate CS.

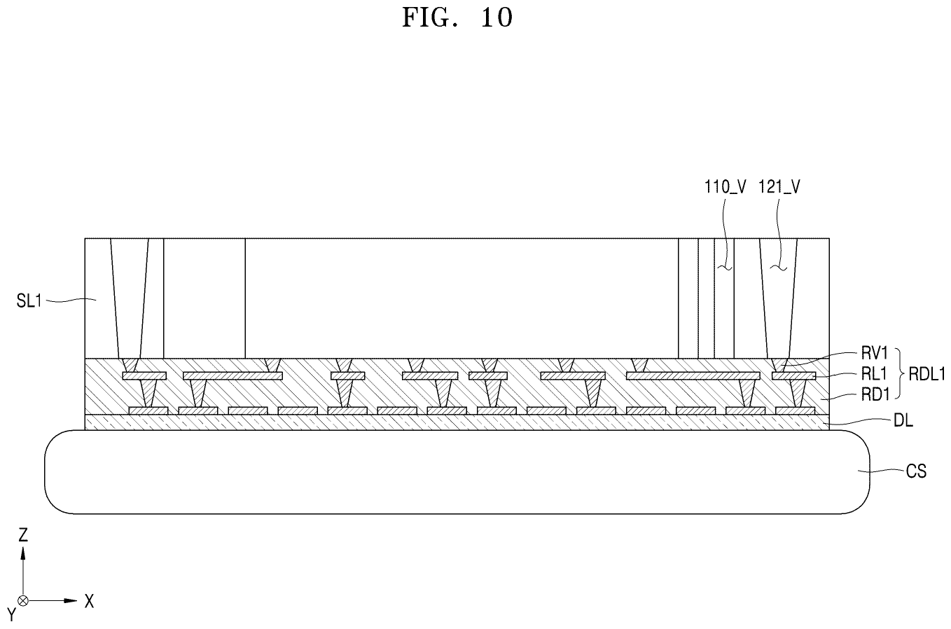

Referring to FIGS. 10 to 12, the conductive post 120a and the conductive plates 110 may be formed on the lower redistribution layer RDL1. Here, the conductive post 120a may include the upper conductive post 122 and the lower conductive post 121.

A first sacrificial insulating layer SL1 may be formed on the lower redistribution layer RDL1, and a plurality of vias penetrating through the first sacrificial insulating layer SL1 may be formed. The vias may include a lower post via 121_V and a plurality of plate vias 110_V. A horizontal width of the lower post via 121_V may decrease toward the lower redistribution layer RDL1. In FIG. 10, the plate vias 110_V are shown to have a constant horizontal width, but the disclosure is not limited thereto, and like the lower post via 121_V, the plate vias 110_V may have the horizontal width D_121 varying toward the lower redistribution layer RDL1.

Next, through a plating process, the lower post via 121_V and the plate vias 110_V may be filled with a conductive material to form the lower conductive post 121 and the conductive plates 110. The lower conductive post 121 and the conductive plates 110 may directly contact and be electrically connected to the lower redistribution layer RDL1.

In some embodiments, a distance between two adjacent plate vias 110_V in the second horizontal direction (D2 in FIG. 1) may be about 3 μm to about 40 μm. Accordingly, a distance P_110 between two adjacent conductive plates 110 in the second horizontal direction (D2 in FIG. 1) may be about 3 μm to about 40 μm.

In some embodiments, a diameter D_120a of the conductive post 120a may be less than the length W_110 of each of the conductive plates 110 in the first horizontal direction (D1 in FIG. 1) and greater than the length L_110 of each of the conductive plates 110 in the second horizontal direction (D2 in FIG. 1).

In some embodiments, the length H_121 of the lower conductive post 121 in the vertical direction (the Z direction) may be equal to the length H_110 of each of the conductive plates 110 in the vertical direction (the Z direction). For example, because the lower post via 121_V and the plate vias 110_V completely penetrate through the first sacrificial insulating layers SL1, the length H_121 of the lower conductive post 121 in the vertical direction (the Z direction) and the length H_110 of each of the conductive plates 110 in the vertical direction (the Z direction) may be equal to the length of the first sacrificial insulating layer SL1 in the vertical direction (the Z direction). For example, the upper surface of the lower conductive post 121 may be coplanar with the upper surface of the conductive plates 110.

Next, a second sacrificial insulating layer SL2 may be formed on the first sacrificial insulating layer SL1, the lower conductive post 121, and the conductive plates 110, and an upper post via 122_V may be formed.

The upper post via 122_V may be formed on the lower conductive post 121. The upper post via 122_V may completely penetrate through the second sacrificial insulating layer SL2 and communicate with the lower post via 121_V. A horizontal width of the upper post via 122_V may decrease toward the lower redistribution layer RDL1. Accordingly, the horizontal width D_122 of the upper conductive post 122 may decrease toward the lower redistribution layer RDL1.

Thereafter, the upper post via 122_V may be filled with a conductive material through a plating process to form the upper conductive post 122. The upper conductive post 122 may be electrically connected to the lower conductive post 121 to form one conductive post 120a.

In some embodiments, the horizontal width D_122 of the lower surface of the upper conductive post 122 may be different from the horizontal width D_121 of the upper surface of the lower conductive post 121. For example, the horizontal width D_122 of the lower surface of the upper conductive post 122 may be less than the horizontal width D_121 of the upper surface of the lower conductive post 121.

Thereafter, the first sacrificial insulating layer SL1 and the second sacrificial insulating layer SL2 may be removed, and the first semiconductor chip 100 may be attached to the central region of the lower redistribution layer RDL1. In some embodiments, the chip pad 101 formed on the active surface of the first semiconductor chip 100 may be electrically connected to the lower redistribution layer RDL1 through the connection terminal 102.

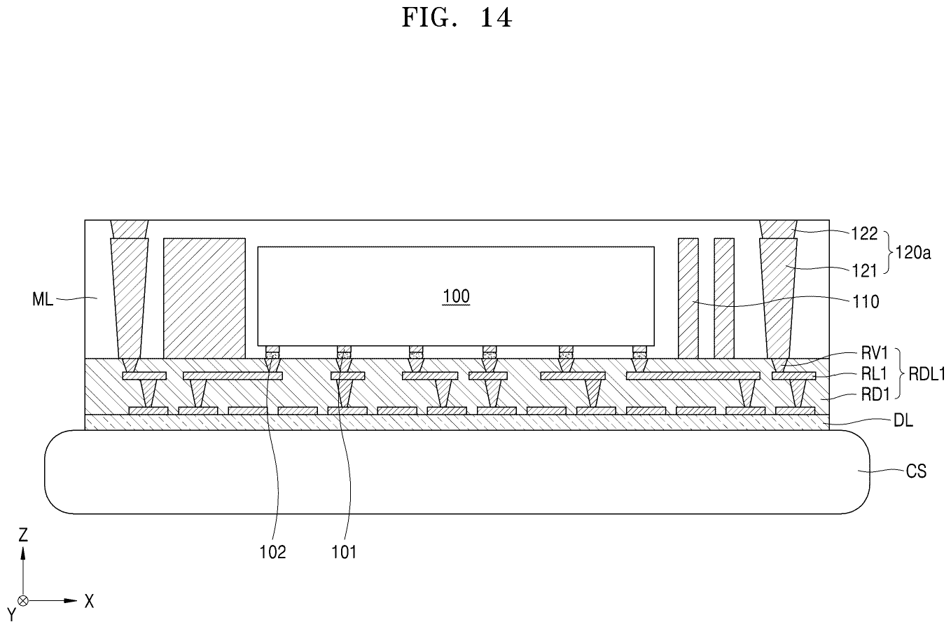

Referring to FIG. 14, the molding layer ML may be formed to surround the first semiconductor chip 100, the conductive plates 110, and the conductive post 120a.

In some embodiments, after forming the molding layer ML thick enough to cover the top of the first semiconductor chip 100, the conductive plates 110, and the conductive post 120a, the upper portion of the molding layer ML may be removed through a grinder so that the upper surface of the conductive post 120a is exposed externally. Here, the conductive plates 110 may be buried within the molding layer ML. That is, the molding layer ML formed on the top of the conductive plates 110 may remain.

In some embodiments, the upper surface of the molding layer ML may be coplanar with the upper surface of the conductive post 120a. In some embodiments, when the upper portion of the molding layer ML is removed so that the conductive plates 110 are exposed externally, the upper surfaces of the conductive plates 110, the upper surface of the conductive post 120a, and the upper surface of the molding layer ML may be coplanar with each other.

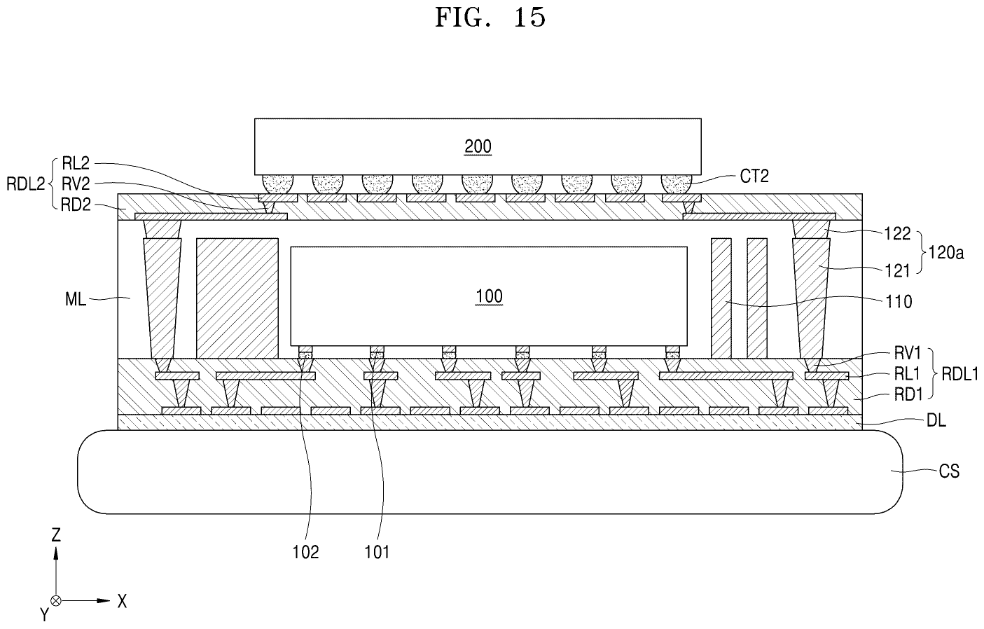

Referring to FIG. 15, the upper redistribution layer RDL2 may be formed on the molding layer ML and the conductive post 120a.

The upper surface of the conductive post 120a may directly contact the upper redistribution layer RDL2. For example, the conductive post 120a may be electrically connected to the upper redistribution layer RDL2. Accordingly, the upper redistribution layer RDL2 may be electrically connected to the lower redistribution layer RDL1 through the conductive post 120a. The conductive posts 120a may be separated from the upper redistribution layer RDL2 in the vertical direction (the Z direction) with the molding layer ML therebetween.

The upper redistribution layer RDL2 may include the upper interconnection line RL2, the upper vertical via RV2 vertically connecting the upper interconnection line RL2, and the upper insulating layer RD2 surrounding the periphery of the upper interconnection line RL2 and the upper vertical via RV2.

Here, according to the formation process of the upper vertical via RV2, structurally, the horizontal area of the upper vertical via RV2 located inside the upper redistribution layer RDL2 may decrease toward the first semiconductor chip 100.

Referring to FIG. 15, the second semiconductor chip 200 may be disposed on the upper redistribution layer RDL2.

The second semiconductor chip 200 may be disposed on the upper redistribution layer RDL2 with the active surface of the second semiconductor chip 200 facing the upper redistribution layer RDL2. Here, the second semiconductor chip 200 may be electrically connected to the upper redistribution layer RDL2 through the internal connection terminal CT2 formed between the second semiconductor chip 200 and the upper redistribution layer RDL2.

The second semiconductor chip 200 may be electrically connected to the lower redistribution layer RDL through the internal connection terminal CT2, the upper redistribution layer RDL2, and the conductive post 120. However, the method of disposing the second semiconductor chip 200 on the upper redistribution layer RDL2 is not limited thereto.

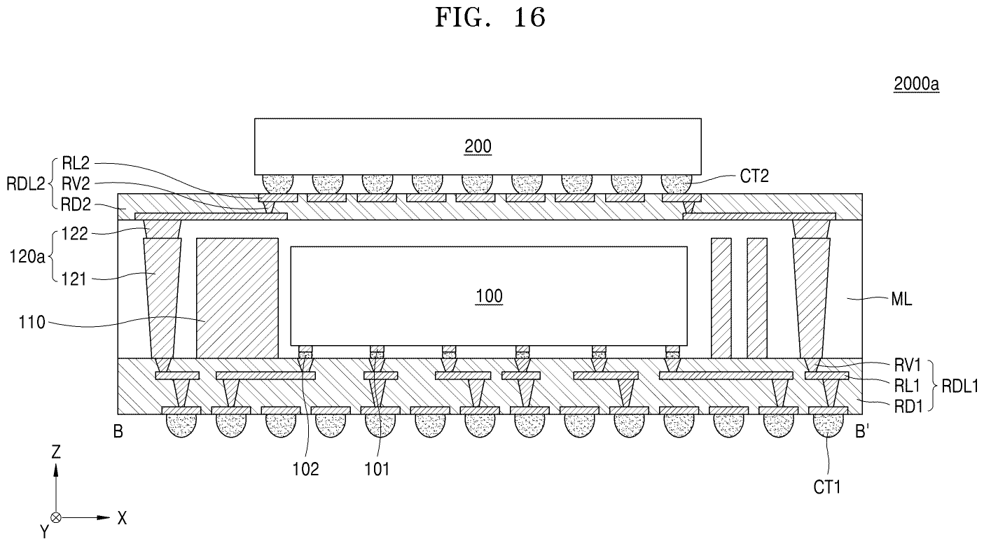

Referring to FIG. 16, the carrier substrate CS may be removed, and the external connection terminal CT1 may be formed on the lower surface of the lower redistribution layer RDL1. The external connection terminal CT1 may include, for example, a solder ball, a conductive bump, a conductive paste, or BGA. The external connection terminal CT1 may be formed on a lower interconnection pad connected to the lower interconnection line RL1 of the lower redistribution layer RDL1.

While certain embodiments of the disclosure has been particularly shown and described, it will be understood that various changes in form and details may be made therein without departing from the spirit and scope of the following claims.

What is claimed is:

1. A semiconductor package comprising:
a lower redistribution layer;
a semiconductor chip on an upper surface of the lower redistribution layer, the semiconductor chip having an area that is less than an area of the lower redistribution layer;
at least one plate group on the upper surface of the lower redistribution layer, each of the at least one plate group comprising a plurality of conductive plates facing each other and extending in a same direction; and
a molding layer covering the upper surface of the lower redistribution layer and surrounding the semiconductor chip and the at least one plate group,
wherein the plurality of conductive plates extend along a plane on the upper surface of the lower redistribution layer in a first horizontal direction and a second horizontal direction perpendicular to the first horizontal direction, and each of the plurality of conductive plates has a length in the first horizontal direction that is greater than a length in the second horizontal direction.

2. The semiconductor package of claim 1, further comprising at least one external connection terminal uniformly disposed on a lower surface of the lower redistribution layer.

3. The semiconductor package of claim 1, wherein the plurality of conductive plates in each of the at least one plate group are spaced apart from each other at equal intervals in the second horizontal direction, and
wherein the molding layer is in a space between the plurality of conductive plates.

4. The semiconductor package of claim 3, wherein two adjacent conductive plates of the plurality of conductive plates of each of the at least one plate group are separated from each other by about 3 μm to about 40 μm in the second horizontal direction.

5. The semiconductor package of claim 1, wherein the first horizontal direction of the plurality of conductive plates of each of the at least one plate group is not parallel to an extension direction of an edge of the semiconductor chip.

6. The semiconductor package of claim 1, wherein a cross-section of each of the plurality of conductive plates of each of the at least one plate group has a bent shape.

7. The semiconductor package of claim 1, wherein a length of each of the plurality of conductive plates of each of the at least one plate group in a vertical direction is less than or equal to a length of the molding layer in the vertical direction.

8. The semiconductor package of claim 1, wherein the length of each of the plurality of conductive plates of each of the at least one plate group in the first horizontal direction is 10 to 100 times the length of each of the plurality of conductive plates of each of the at least one plate group in the second horizontal direction.

9. The semiconductor package of claim 1, wherein the length in the second horizontal direction of each of the plurality of conductive plates of each of the at least one plate group is about 20 μm to about 100 μm.

10. The semiconductor package of claim 1, wherein the at least one plate group comprises a first plate group and a second plate group, and
wherein the first horizontal direction of the plurality of conductive plates of the first plate group is different from the first horizontal direction of the plurality of conductive plates of the second plate group.

11. A semiconductor package comprising:
a lower redistribution layer;
a semiconductor chip on an upper surface of the lower redistribution layer, the semiconductor chip having an area that is less than an area of the lower redistribution layer;
a conductive post on the upper surface of the lower redistribution layer and spaced apart from the semiconductor chip in a horizontal direction;
a plate group on the upper surface of the lower redistribution layer, the plate group comprising a plurality of conductive plates facing each other and extending in a same direction;
a molding layer covering the upper surface of the lower redistribution layer and surrounding the semiconductor chip, the conductive post, and the plate group; and
an upper redistribution layer on the molding layer and the conductive post,
wherein the plurality of conductive plates extend along a plane on the upper surface of the lower redistribution layer in a first horizontal direction and a second horizontal direction perpendicular to the first horizontal direction, and each of the plurality of conductive plates has a length in the first horizontal direction that is greater than a length in the second horizontal direction.

12. The semiconductor package of claim 11, wherein the plate group is between the conductive post and the semiconductor chip.

13. The semiconductor package of claim 11, wherein a length of the conductive post in a vertical direction is greater than a length of the plurality of conductive plates of the plate group in the vertical direction.

14. The semiconductor package of claim 11, wherein upper surfaces of the plurality of conductive plates of the plate group are spaced apart from a lower surface of the upper redistribution layer with the molding layer therebetween.

15. The semiconductor package of claim 11, wherein the conductive post has a circular cross-section, and
wherein a diameter of the conductive post is less than the length of the plurality of conductive plates of the plate group in the first horizontal direction and greater than the length of the plurality of conductive plates of the plate group in the second horizontal direction.

16. The semiconductor package of claim 11, wherein a material of the plurality of conductive plates of the plate group is the same as a material of the conductive post.

17. The semiconductor package of claim 11, wherein the conductive post comprises an upper post and a lower post having a horizontal width decreasing toward the lower redistribution layer, and
wherein an area of a lower surface of the upper post is less than an area of an upper surface of the lower post.

18. The semiconductor package of claim 17, wherein a length of the lower post of the conductive post in a vertical direction is equal to a length of the plurality of conductive plates of the plate group in the vertical direction.

19. A semiconductor package comprising:
a lower redistribution layer;
a semiconductor chip on an upper surface of the lower redistribution layer, the semiconductor chip having an area that is less than an area of the lower redistribution layer;
a conductive post on the upper surface of the lower redistribution layer and space apart from the semiconductor chip in a horizontal direction, the conductive post having a cylindrical shape;
a first plate group comprising a plurality of first conductive plates on the upper surface of the lower redistribution layer and between the conductive post and the semiconductor chip, the plurality of first conductive plates facing each other and extending in a first same direction;
a second plate group comprising a plurality of second conductive plates on the upper surface of the lower redistribution layer and between the conductive post and the semiconductor chip, facing each other, the plurality of second conductive plates extending in a second same direction;
a molding layer covering the upper surface of the lower redistribution layer and surrounding the semiconductor chip, the conductive post, the first plate group, and the second plate group; and
an upper redistribution layer on the molding layer and the conductive post,
wherein each of the plurality of first conductive plates extends along a plane on the lower redistribution layer in a first horizontal direction and a second horizontal direction perpendicular to the first horizontal direction, and the first horizontal direction of the plurality of first conductive plates is different from the first horizontal direction of the plurality of second conductive plates,
wherein a length of a diameter of the conductive post is less than a length of each of the plurality of first conductive plates in the first horizontal direction and greater than a length each of the plurality of first conductive plates in the second horizontal direction, and
wherein the length of the diameter of the conductive post is less than a length of each of the plurality of second conductive plates in the first horizontal direction and greater than a length of each of the plurality of second conductive plates in the second horizontal direction.

20. The semiconductor package of claim 19, wherein the conductive post directly contacts the lower redistribution layer and the upper redistribution layer, and
wherein the first plate group and the second plate group are spaced apart from the upper redistribution layer in a vertical direction with the molding layer therebetween.
